(19) United States
(12) Patent Application Publication
(10) Pub. No.: US 2020/0075468 A1
(43) Pub. Date: Mar. 5, 2020

(54) Dedicated Integrated Circuit Chip Carrier Plane Connected to Decoupling Capacitor(s)

(71) Applicant: International Business Machines Corporation, Armonk, NY (US)

(72) Inventors: Charles L. Arvin, Poughkeepsie, NY (US); Franklin M. Baez, Fishkill, NY (US); Francesco Preda, New Braunfels, TX (US)

(21) Appl. No.: 16/120,782

(22) Filed: Sep. 4, 2018

(51) Int. Cl. H01L 23/498; H01L 25/16; H01L 49/02

(52) U.S. Cl. CPC H01L 23/49822; H01L 23/49838; H01L 23/3672; H01L 25/16; H01L 28/40; H01L 23/49866

(57) ABSTRACT

An integrated circuit (IC) chip carrier includes one or more internal metal planes. A dedicated metal plane (DMP) may be formed upon a metal plane dielectric layer. The metal plane dielectric layer may be formed upon a first dielectric layer that is formed upon an IC chip carrier core. The DMP may be formed of the same or different material relative to the material of the wires of the IC chip carrier. The side surfaces of the DMP may be coplanar with associated side surfaces of the IC chip carrier. The DMP may transfer heat from the IC chip horizontally to its side surfaces. A decoupling capacitor is externally connected to the IC chip carrier and is electrically connected to the DMP. By connecting the decoupling capacitor to the DMP, the decoupling capacitor may further reduce inductance and noise within the IC chip system.

### FIELD OF THE EMBODIMENTS

Embodiments of the present invention generally relate to electronic components, such as an electronic package, that include integrated circuit (IC) chip carrier and one or more decoupling capacitors connected externally to the IC chip carrier. The IC chip carrier includes an internal metal plane that is connected the one or more decoupling capacitors.

### DESCRIPTION OF THE RELATED ART

As clock speeds and circuit densities IC chips have increased, degraded electrical performance of the IC chips has been seen due to high frequency noise and inductance. One such cause of noise and inductance is related to the rapid turning on and off of circuits within the IC chip. Some IC chips utilize a power supply of the associated higher-level electronic device as a power source to cycle the turning on and off of the various circuits within the IC chip. Because the distance between the power supply and IC chip is usually orders of magnitude larger than the lengths of the circuits within the IC chip, a large inductance may be introduced. Likewise, the turning on and off of an increasingly large number of circuits within the IC chip results in an increasing amount of noise. Therefore, there is a need to reduce inductance and noise within IC chips.

Increasing IC chip performance leads to the associated increased need to dissipate or remove heat from the IC chip. Typically, a vertical heat dissipation path has been used to remove heat from IC chips. In such vertical heat dissipation paths, heat generated by the IC chip is transferred vertically through the IC chip, to a cover above the IC chip, and finally to a heatsink above the cover.

### SUMMARY

In embodiments, an integrated circuit (IC) chip carrier package, an electronic system, and an IC chip carrier are presented. Such systems include an IC chip carrier and a capacitor. The IC chip carrier includes a core comprising one or more core layers, a first dielectric wiring layer directly upon the core, a metal plane dielectric layer directly upon the first dielectric wiring layer, a dedicated metal plane (DMP) directly upon the metal plane dielectric layer, and one or more dielectric wiring layers directly upon the DMP. The DMP includes a first side surface that is coplanar with a first side surface of the IC chip carrier, a second side surface that is coplanar with a second side surface of the IC chip carrier, a front surface that is coplanar with a front surface of the IC chip carrier, and a rear surface that is coplanar with a rear surface of the IC chip carrier. The one or more dielectric wiring layers are directly upon the DMP and include a first wiring feature upon the IC chip carrier upper surface that is electrically connected to the DMP. One or more decoupling capacitors are connected to the IC chip carrier upper surface. Each capacitor includes a first terminal connected to the first wiring feature and as such, is connected to the DMP. When the capacitor(s) are connected to the DMP, there is a relatively lower inductance between the capacitors and the DMP that, in turn, provides for for improved charging and discharging from the capacitors to the IC.

These and other embodiments, features, aspects, and advantages will become better understood with reference to the following description, appended claims, and accompanying drawings.

### BRIEF DESCRIPTION OF THE FIGURES

So that the manner in which the above recited features of the present invention are attained and can be understood in detail, a more particular description of the invention, briefly summarized above, may be had by reference to the embodiments thereof which are illustrated in the appended drawings.

It is to be noted, however, that the appended drawings illustrate only typical embodiments of this invention and are therefore not to be considered limiting of its scope, for the invention may admit to other equally effective embodiments.

FIG. 1 depicts a cross section of a prior art electronic system.

FIG. 2 depicts a cross-section view of an IC chip carrier and a decoupling capacitor connected externally to the IC chip carrier, according to one or more embodiments of the present invention.

FIG. 3 depicts a normal view of an upper surface of the IC chip carrier, according to one or more embodiments of the present invention.

FIG. 4 depicts a normal view of a metal plane internal to the IC chip carrier that is electrically connected to the decoupling capacitor, according to one or more embodiments of the present invention.

FIG. 5 depicts a cross section of an electronic system that includes the IC chip carrier and the decoupling capacitor, according to one or more embodiments of the present invention.

### DETAILED DESCRIPTION

An integrated circuit (IC) chip carrier includes one or more internal metal planes. The metal plane may be formed upon a metal plane (MP) dielectric layer. The MP dielectric layer may be formed upon a first dielectric layer that is formed upon an IC chip carrier core. The DMP may be formed of the same or different material relative to the material the wires of the IC chip carrier. The side surfaces of the DMP may be coplanar with associated side surfaces of the IC chip carrier. The DMP may transfer heat from the IC chip horizontally to its side surfaces. A decoupling capacitor is externally connected to the IC chip carrier and is electrically connected to the DMP. By connecting the decoupling capacitor to the DMP, the decoupling capacitor may further reduce inductance and noise within the IC chip system.

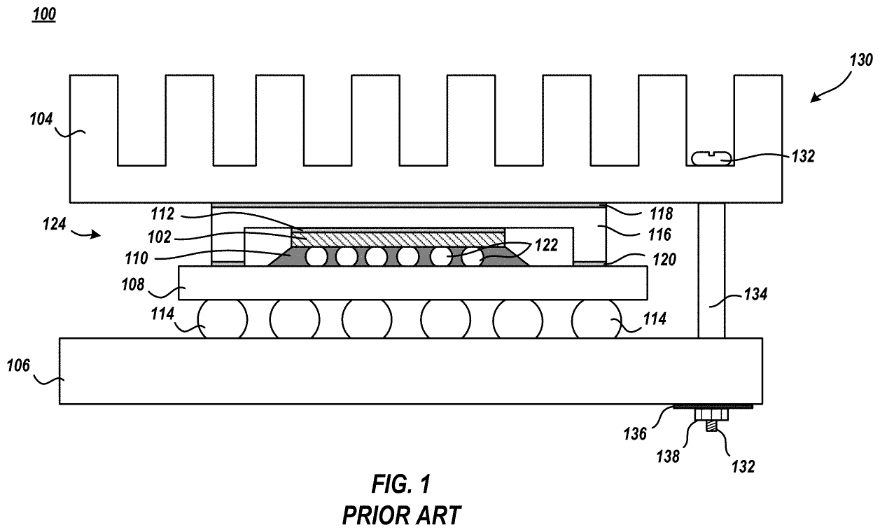

FIG. 1 depicts a prior art electronic system 100 that includes an IC carrier package 124. Electronic system 100 may be for example a computer, server, mobile device, tablet, and the like. Package 124 includes chip 102, carrier 108, interconnects 122, underfill 110, thermal interface material 112, lid 116, and adhesive 120. Chip 102 may be an IC chip, semiconductor die, processor, microchip, field programmable gate array, or the like. Carrier 108 may be an organic carrier or a ceramic carrier and provides mechanical support for chip 102 and electrical paths from the upper surface of carrier 108 to the opposing side of carrier 108. Interconnects 122 electrically connect chip 102 and the upper side of carrier 108 and may be a wire bond, solder bond, stud, conductive ball, conductive button, and the like. Underfill 110 may be electrically-insulating, may substantially surround interconnects 122, may electrically isolate individual interconnects 122, and may provide mechanical support between chip 102 and carrier 108. Underfill 110 may also prevent damage to individual interconnects 122 due to thermal expansion mismatches between chip 102 and carrier 108.

When chip 102 is seated upon carrier 108, a reflow process may be performed to join interconnects 122 to electrical contacts of both chip 122 and carrier 108. After chip 102 is seated to carrier 108, a lid 116 is attached to carrier 108 with adhesive 120 to cover chip 102. Generally, during operation of electronic system 100, heat is removed from chip 102. In this situation, lid 116 is both a cover and a conduit for heat transfer. As such, a thermal interface material 112 may thermally join lid 116 and chip 102.

Package 124 may be connected to a motherboard 106 via interconnects 114. Motherboard 106 may be the main printed circuit board of electronic system 100 and includes electronic components, such as a graphics processing unit, memory, and the like, and provides connectors for other peripherals. Interconnects 114 electrically connect the lower side of carrier 108 to motherboard 106 and may be a wire bond, solder bond, stud, conductive ball, conductive button, and the like. Interconnects 114 may be larger and thus more robust than interconnects 122. When package 124 is seated upon motherboard 106 a second reflow process may be performed to join interconnects 114 to electrical contacts of both carrier 108 and motherboard 106. Alternately, a mechanical pressurized interconnect via an intervening socket may be established.

To assist in the removal of heat from chip 102, a heatsink 104 may be thermally joined to package 124 via thermal interface material 118. Heatsink 104 cools chip 102 by dissipating heat into the surrounding air. As such, during operation of electronic system 100, a substantially vertical thermal path (i.e. most common direction of heat transfer is parallel to the y axis) exists through chip 102 to heatsink 104 through thermal interface material 112, lid 116, and thermal interface material 118, and the like. Heatsink 104 may be connected to motherboard 106 via one or more connection device 130. Connection device 130 may include a threaded fastener 132, standoff 134, backside stiffener 136, and fastener 138. Threaded fastener 132 may extend through heatsink 104, standoff 134, and backside stiffener 136 and provides compressive force between heatsink 104 and backside stiffener 136. The length of standoff 134 may be selected to limit the pressure exerted upon package 124 by heatsink 104 created by the compressive forces. Backside stiffener 136 may mechanically support the compressive forces by distributing the forces across a larger area of motherboard 104. In other applications, connection device 130 may be a clamp, non-influencing fastener, cam, and the like, system that adequately forces heatsink 104 upon package 124.

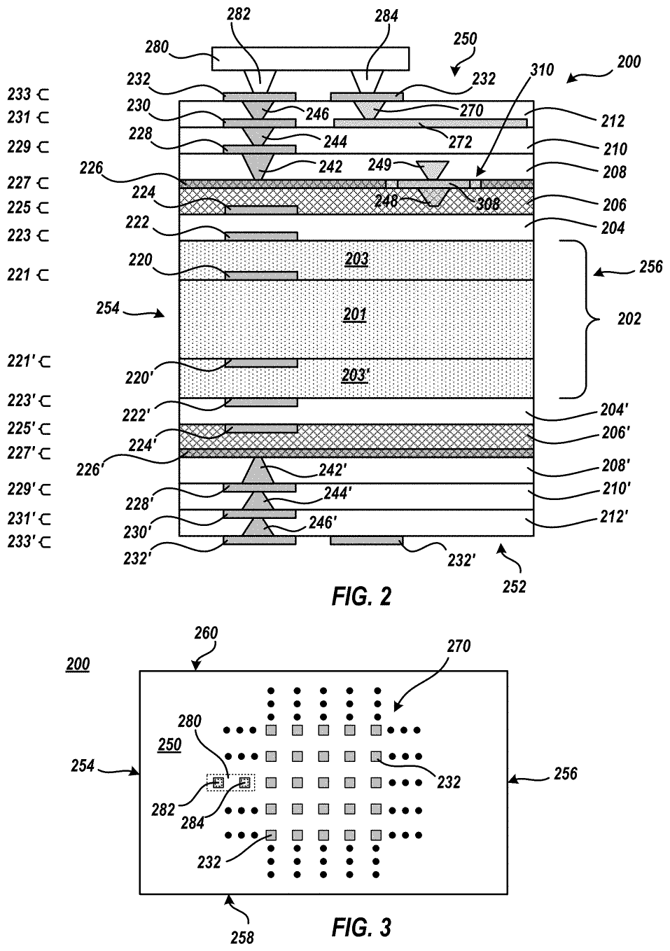

FIG. 2 depicts a cross-section view of IC chip carrier 200 and decoupling capacitor 280 connected externally to the IC chip carrier 200, according to one or more embodiments of the present invention. IC chip carrier 200 may include a core 202, a first dielectric build-up layer 204 directly upon an upper side of the core 202, a MP dielectric layer 206 directly upon the first dielectric layer 204, DMP 226 directly upon the MP dielectric layer 206, a second dielectric build-up layer 208 directly upon the DMP 226, a third dielectric build-up layer 210 directly upon the second dielectric build-up layer 208, and a fourth dielectric build-up layer 212 directly upon the third dielectric build-up layer 210. Core 202 may be a single layer or may include multiple core layers 201, 203, and 203′.

IC chip carrier 200 may further include a first dielectric build-up layer 204′ directly upon a lower side of the core 202, a MP dielectric layer 206′ directly upon the first dielectric layer 204′, DMP 226′ directly upon the MP dielectric layer 206′, a second dielectric build-up layer 208′ directly upon the DMP 226′, a third dielectric build-up layer 210′ directly upon the second dielectric build-up layer 208′, and a fourth dielectric build-up layer 212′ directly upon the third dielectric build-up layer 210′.

A wire feature 220 may be formed directly upon or within core layer 201. A wire feature 222 may be formed directly upon or within core layer 203. Likewise, a wire feature 224 may be formed upon or within the first dielectric build-up layer 204, a wire feature 228 may be formed upon or within the second dielectric build-up layer 208, a wire feature 230 may be formed upon or within the third dielectric build-up layer 210, and a wire feature 232 may be formed upon or within the fourth dielectric build-up layer 212.

Wire feature 220 may be within a wiring layer 221 closest to core layer 201, wire feature 220 may be within a wiring layer 223 that is above wiring layer 221, wire feature 224 may be within a wiring layer 225 that is above wiring layer 223, DMP 226 may be within a wiring layer 227 that is above wiring layer 225, wire feature 228 is generally within a wiring layer 229 that is above wiring layer 227, wire feature 230 is generally within a wiring layer 231 that is above wiring layer 229, and wire feature 232 is generally within a wiring layer 233 that is above wiring layer 231.

A wire feature 220′ may be formed directly upon or within core layer 201′. A wire feature 222′ may be formed directly upon or within core layer 203′. Likewise, a wire feature 224′ may be formed upon or within the first dielectric build-up layer 204′, a wire feature 228′ may be formed upon or within the second dielectric build-up layer 208′, a wire feature 230′ may be formed upon or within the third dielectric build-up layer 210′, and a wire feature 232′ may be formed upon or within the fourth dielectric build-up layer 212′.

Wire feature 220′ may be within a wiring layer 221′ closest to core layer 201′, wire feature 220′ may be within a wiring layer 223′ that is below wiring layer 221′, wire feature 224′ may be within a wiring layer 225′ that is below wiring layer 223′, DMP 226′ may be within a wiring layer 227′ that is below wiring layer 225′, wire feature 228′ is generally within a wiring layer 229′ that is below wiring layer 227′, wire feature 230′ is generally within a wiring layer 231′ that is below wiring layer 229′, and wire feature 232′ is generally within a wiring layer 233′ that is below wiring layer 231′.

If a wire feature is formed directly upon a layer, the surface of the wire feature that faces that layer is generally coplanar with the surface of the underlying layer that faces the wire feature. If a wire feature is formed within a layer, an exposed surface of the wire feature is generally coplanar with a surface of the layer.

A wire feature may be formed upon a layer by depositing, applying, coating, printing, etc. the wire feature directly upon the layer. Alternatively, a wire feature may be formed upon a layer by deposing, applying, coating, printing, or the like, a conductive sheet directly upon the layer and removing undesired portions of the conductive sheet from the layer, thereby leaving the wire feature upon the layer.

The term “wire feature” is defined herein to be a electrically conductive structure for the receipt, handling, or transfer of signals, electric potential, or the like and may be e.g., a wire, pad, trace, or the like. In an implementation, each wire feature is formed of Copper.

An inter-wiring layer connection feature 242 within second dielectric build-up layer 208 may be connected to both wire feature 228 and DMP 226. An inter-wiring layer connection feature 244 within third dielectric build-up layer 210 may be connected to both wire feature 230 and wire feature 228. An inter-wiring layer connection feature 246 within fourth dielectric build-up layer 212 may be connected to both wire feature 232 and wire feature 230.

An inter-wiring layer connection feature 242′ within second dielectric build-up layer 208′ may be connected to both wire feature 228′ and DMP 226′. An inter-wiring layer connection feature 244′ within third dielectric build-up layer 210′ may be connected to both wire feature 230′ and wire feature 228′. An inter-wiring layer connection feature 246′ within fourth dielectric build-up layer 212′ may be connected to both wire feature 232′ and wire feature 230′.

The term “inter-wiring layer connection feature” is defined herein to be an electrically conductive structure that connects an electrically conductive structure that is directly upon and above the layer in which the inter-wiring layer connection feature is within with an electrically conductive structure that is upon and below the layer in which the inter-wiring layer connection feature is within. In an implementation, each inter-wiring layer connection feature is formed of Copper.

Core layer 203′ and wiring layer 221′ may be in a position within carrier 200 relative to core layer 201 such that core layer 203′ and wiring layer 221′ are a reflection of core layer 203 and wiring layer 221 across core layer 201, respectively. First dielectric build-up layer 204′ and wiring layer 223′ may be in a position within carrier 200 relative to core 202 such that first dielectric build-up layer 204′ and wiring layer 223′ is a reflection of first dielectric build-up layer 204 and wiring layer 223 across core 202, respectively. MP dielectric layer 206′ and wiring layer 227′ may be in a position within carrier 200 relative to core 202 such that MP dielectric layer 206′ and wiring layer 227′ is a reflection of MP dielectric layer 206 and wiring layer 227 across core 202, respectively. Second dielectric build-up layer 208′ and wiring layer 229′ may be in a position within carrier 200 relative to core 202 such that second dielectric build-up layer 208′ and wiring layer 229′ is a reflection of second dielectric build-up layer 208 and wiring layer 229 across core 202, respectively. Third dielectric build-up layer 210′ and wiring layer 231′ may be in a position within carrier 200 relative to core 202 such that third dielectric build-up layer 210′ and wiring layer 331′ is a reflection of third dielectric build-up layer 210 and wiring layer 331 across core 202, respectively. Fourth dielectric build-up layer 212′ and wiring layer 233′ may be in a position within carrier 200 relative to core 202 such that fourth dielectric build-up layer 212′ and wiring layer 333′ is a reflection of fourth dielectric build-up layer 212 and wiring layer 333 across core 202, respectively.

Inter-wiring layer connection feature 242′ may be in a position within carrier 200 relative to core 202 such that inter-wiring layer connection feature 242′ is a reflection of inter-wiring layer connection feature 242 across core 202. Inter-wiring layer connection feature 244′ may be in a position within carrier 200 relative to core 202 such that inter-wiring layer connection feature 244′ is a reflection of inter-wiring layer connection feature 244 across core 202. Inter-wiring layer connection feature 246′ may be in a position within carrier 200 relative to core 202 such that inter-wiring layer connection feature 246′ is a reflection of inter-wiring layer connection feature 246 across core 202.

Carrier 200 may also include a power/ground plane 272. The term “power/ground plane” is defined herein to be an electrically conductive structure that provides electric potential, ground, or the like to circuits within or attached to carrier 200 and has an opposite or different polarity relative to the polarity of DMP 226. In an implementation, power/ground plane 272 is formed of Copper. Though power/ground plane 272 is shown in wiring level 231, power/ground plane 272 may be located within wiring level 229, 227, 225, 223, or 221. Inter-wiring layer connection feature(s) and/or wiring feature(s) may be located upon or otherwise above the power/ground plane 272 such that power/ground plane 272 is electrically connected to a wiring feature 232 on external surface of carrier 200. For example, as depicted, carrier 200 may include an inter-wiring layer connection feature 270 that is connected to DMP 226 and wiring feature 232.

Though one wire feature is depicted in wiring layers 221, 221′, 223, 223′, 225, 225′, 229, 229′, 231′, or the like, multiple wire features may exist within such or other wiring layers within carrier 200. Tough one inter-wiring layer connection features are depicted within exemplary layers, multiple inter-wiring layer connection features may exist within such or other layers within carrier 200.

ML 226 may include one or more clearance holes 310 to allow for wiring feature(s) and/or inter-wiring layer connection feature(s) to pass therethrough without contacting ML 226. For example, wiring feature 308 also within wiring level 227 may be located within clearance hole 310. Inter-wiring layer connection feature 249 may be connected to wiring feature 308 above wiring feature 308 and inter-wiring layer connection feature 248 may be connected to wiring feature 308 below feature 308. Clearance hole(s) 310 may further allow for the layer there above and the layer there below to contact and adhere together and may therefore improve adhesion within the buildup of carrier 200. For example, clearance hole 310 allows for second dielectric build-up layer 208 to contact and adhere with MP dielectric layer 206. Adhesion between such layers may be greater than the relative adhesion between second dielectric build-up layer 208 and DMP 226 and between MP dielectric layer 206 and DMP 226, respectively. As such, the adhesion within the buildup of carrier 200 may be improved.

Carrier 200 may include a top surface 250, a bottom surface 252, a side surface 254, a side surface 256, a front surface 258, as shown in FIG. 3, and a rear surface 260 as shown in FIG. 3. Side surface 254 and side surface 256 may be formed by coplanar side surfaces of the various layers or structures within the build up of carrier 200.

Decoupling capacitor 280 may be electrically connected to the upper surface 250 of carrier 200. For example, a terminal 282 of capacitor 280 may contact a wiring feature 232 on the supper surface 250 of carrier 200 and a terminal 284 of capacitor 280 may contact a wiring feature 232 on the supper surface 250 of carrier 200. The terminal 282 may be electrically connected to DMP 226 and the terminal 284 may be electrically connected to power/ground plane 272. In a specific implantation, DMP 226 has a non-zero potential (i.e., power potential, etc.) and power/ground plane 272 has a zero potential (i.e., ground, etc.). In another implantation, DMP 226 has a zero potential (i.e., ground potential, etc.) and power/ground plane 272 has a non-zero potential (i.e., power potential, etc.). As such, the electric polarities of terminal 282 and terminal 284 are different. The terminal 282 of capacitor 280 is electrically connected to a first capacitor plate within capacitor 280 as is known in the art. Further, the terminal 284 of capacitor 280 is electrically connected to a second capacitor plate within capacitor 280 as is known in the art. The first capacitor plate and the second capacitor plate is separated by a dielectric thus forming capacitor 280, as is known in the art.

The term dedicated metal plane or the like is herein defined to be a metal plane that is devoted to one or more capacitors such that when the capacitors are electrically connected to the DMP, there is a relatively lower inductance between the capacitors and the DMP that, in turn, provides for improved charging and discharging from the capacitors to the IC. The DMP may be in an associated location within the cross section of carrier 200 to provide the greatest opportunity to reduce large holes 310 within the DMP and thereby reduce the overall inductance loop between the capacitor(s) 280 and DMP. The DMP may be in an associated location within the cross section of carrier 200 to minimizes the impact to the above wiring layers that require high speed signal escapes and routing.

Unless specified throughout the remainder of this paper, a numeral′ and a numeral may be referred to generically as the numeral.

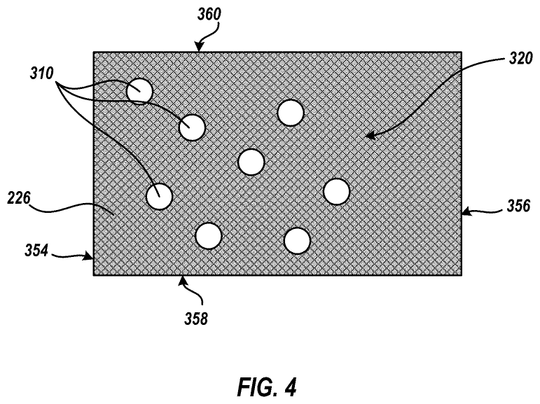

FIG. 3 depicts a normal view of an upper surface 250 of IC chip carrier 200, according to one or more embodiments of the present invention. The upper surface 250 and bottom surface 252 may include a grid 270 of wiring features 270, such as contact pads, or the like. Each contact of a processor 402, shown in FIG. 4, may electrically contact a respective wiring feature 232 on the upper surface 250 of carrier 200. Further, each terminal of a multi terminal capacitor may also electrically contact a respective wiring feature 232 on the upper surface 250 of carrier 200.

FIG. 4 depicts a normal view of DMP 226 internal to the IC chip carrier 200 that is electrically connected to the decoupling capacitor 280, according to one or more embodiments of the present invention. DMP 226 may include a side surface 354, a side surface 356, a front surface 358, and a rear surface 360. In an embodiment, side surface 354 may be coplanar with side surface 254, side surface 356 may be coplanar with side surface 256, front surface 358 may be coplanar with front surface 258, and rear surface 360 may be coplanar with rear surface 260.

In an alternative embodiment, side surface 354 may be inset from side surface 254 a dimension to allow for second dielectric build-up layer 208 to contact and adhere with MP dielectric layer 206, side surface 356 may be inset from side surface 256 to allow for second dielectric build-up layer 208 to contact and adhere with MP dielectric layer 206, front surface 358 may be inset from front surface 258 to allow for second dielectric build-up layer 208 to contact and adhere with MP dielectric layer 206, and rear surface 360 may be inset from rear surface 260 to allow for second dielectric build-up layer 208 to contact and adhere with MP dielectric layer 206.

For clarity, clearance holes 310 may extend through DMP 226 and may thus be voids within such DMP 226.

In an implementation, side surface 354 may be continuous without creases, edges, or the like, therein; side surface 356 may be continuous without creases, edges, or the like, therein; front surface 358 may be continuous without creases, edges, or the like, therein, and rear surface 360 may be continuous without creases, edges, or the like, therein.

In an embodiment, DMP 226 and DMP 226′ may be same metal relative to the wiring features and inter-layer connection features within carrier 200. For example, DMP 226 and DMP 226′ may be a Copper DMP and the wiring features and inter-layer connection features may be Copper, respectively. In alternative embodiments, DMP 226 and DMP 226′ may be a different metal relative to the wiring features and inter-layer connection features within carrier 200. For example, the wring features and inter-layer connection features may be Copper wiring features and Copper inter-layer connection features and the DMP 226 and DMP 226′ may be an Iron Nickel alloy DMP.

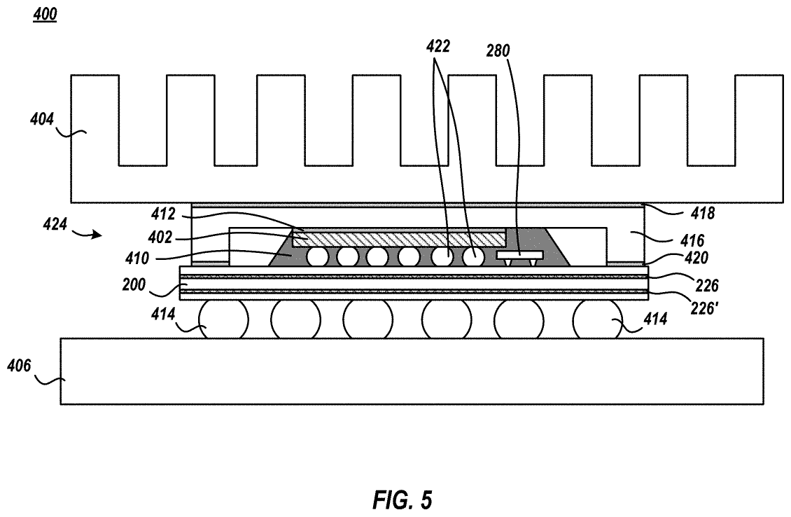

FIG. 5 depicts a cross section of an electronic system 400 that includes the IC chip carrier 200 and the decoupling capacitor 280, according to one or more embodiments of the present invention.

Electronic system 400 may be for example a computer, server, mobile device, tablet, cash machine, kiosk, and the like. Package 424 includes chip 402, carrier 200, interconnects 422, underfill 410, thermal interface material 412, lid 416, and adhesive 420. Chip 402 may be an IC chip, semiconductor die, processor, microchip, field programmable gate array, or the like. Carrier 200 may provide mechanical support for chip 102 and electrical paths from the upper surface 250 of carrier 108 to the opposing surface 252 of carrier 200. Interconnects 422 electrically connect chip 402 with wiring features 232 upon upper surface 250 of carrier 200 and may be a wire bond, solder bond, stud, conductive ball, conductive button, and the like. Underfill 410 may be electrically-insulating, may substantially surround interconnects 422, may electrically isolate individual interconnects 422, and may provide mechanical support between chip 402 and carrier 200. Underfill 410 may also prevent damage to individual interconnects 422 due to thermal expansion mismatches between chip 402 and carrier 200.

When chip 402 is seated upon carrier 200, a reflow process may be performed to join interconnects 422 to contacts of chip 402 with upper surface 250 wiring features 232 of carrier 200. After chip 402 is seated to carrier 200, a lid 416 may be attached to carrier 200 with adhesive 420 to cover chip 402. Generally, during operation of electronic system 400, heat is removed from chip 402. In this situation, lid 416 is both a cover and a conduit for heat transfer. As such, a thermal interface material 412 may thermally join lid 416 and chip 402.

Package 424 may be connected to a motherboard 406 via interconnects 414. Motherboard 406 may be the main printed circuit board of electronic system 400 and includes electronic components, such as a graphics processing unit, memory, and the like, and provides connectors for other peripherals. Interconnects 414 electrically connect the lower surface 252 of carrier 200 to motherboard 406 and may be a wire bond, solder bond, stud, conductive ball, conductive button, and the like. Interconnects 414 may be larger and thus more robust than interconnects 422. When package 424 is seated upon motherboard 406 a second reflow process may be performed to join interconnects 414 to lower surface 252 wiring features 232 of carrier 200 with contacts of motherboard 106. Alternately, a mechanical pressurized interconnect via an intervening socket may be established.

To assist in the removal of heat from chip 402, a heatsink 404 may be thermally joined to package 424 via thermal interface material 418. Heatsink 424 cools chip 402 by dissipating heat into the surrounding air or into a actively circulating coolant. As such, during operation of electronic system 400, a substantially vertical thermal path exists through chip 402 to heatsink 404 through thermal interface material 412, lid 416, and thermal interface material 418, and the like. To further assist in removing heat from chip 402, DMP 226 and DMP 226′ may also transfer heat from chip 402 horizontally or parallel with the upper surface 250 of carrier 200 to e.g., the side surface 254, side surface 256, front surface 258, and/or rear surface 260 of carrier 200.

In an embodiment, capacitor 280 is positioned upon carrier 200 such that a portion of the capacitor 280 is within the footprint of chip 402. Alternatively, capacitor 280 may be positioned upon carrier 200 such that the entire capacitor 280 is within the footprint of chip 402. Alternatively, capacitor 280 may be positioned upon carrier 200 such that none of the capacitor 280 is within the footprint of chip 402. In some embodiments, underfill 410 may substantially surround capacitor 280, as is depicted.

By being connected to DMP 226, the capacitor 280 further reduces the inductance and noise within electronic system 400. Further, by positioning the perimeter side, front, and rear surfaces of DMP 226 and DMP 226′ near the associated perimeter side, front, and rear surface of cattier 200, an increased amount of heat may be transferred horizontally away from chip 402 leading to increased chip 402 performance.

Though one processor 402 is shown in IC chip package 424, IC chip package 424 may include multiple processors 402 as is known in the art.

The accompanying figures and this description depicted and described embodiments of the present invention, and features and components thereof. Those skilled in the art will appreciate that any particular program nomenclature used in this description was merely for convenience, and thus the invention should not be limited to use solely in any specific application identified and/or implied by such nomenclature.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. For example, the order of the fabrication stages listed in depicted blocks may occur out of turn relative to the order indicated in the Figures, may be repeated, and/or may be omitted partially or entirely. The terminology used herein was chosen to best explain the principles of the embodiment, the practical application or technical improvement over technologies found in the marketplace, or to enable others of ordinary skill in the art to understand the embodiments disclosed herein.

References herein to terms such as “vertical”, “horizontal”, and the like, are made by way of example, and not by way of limitation, to establish a frame of reference. The term “horizontal” as used herein is defined as a plane parallel to the conventional plane or upper surface 250 of the carrier 200, regardless of the actual spatial orientation of the carrier 200. The term “vertical” refers to a direction perpendicular to the horizontal, as just defined. Terms, such as “on”, “above”, “below”, “side” (as in “sidewall”), “higher”, “lower”, “over”, “top”, “under”, “beneath”, and the like, are defined with respect to the horizontal plane. It is understood that various other frames of reference may be employed for describing the present invention without departing from the spirit and scope of the present invention.

What is claimed is:

1. An integrated circuit (IC) chip carrier package comprising:
a core comprising one or more core layers;
a first dielectric wiring layer directly upon the core;
a metal plane dielectric layer directly upon the first dielectric wiring layer;
a dedicated metal plane (DMP) directly upon the metal plane dielectric layer, the DMP comprising a first side surface that is coplanar with a first side surface of the IC chip carrier, a second side surface that is coplanar with a second side surface of the IC chip carrier, a front surface that is coplanar with a front surface of the IC chip carrier, and a rear surface that is coplanar with a rear surface of the IC chip carrier;
one or more dielectric wiring layers directly upon the DMP, the one or more dielectric wiring layers comprising a first wiring feature upon the IC chip carrier upper surface that is electrically connected to the DMP; and
a capacitor connected to the IC chip carrier upper surface, the capacitor comprising a first terminal connected to the first wiring feature.

2. The IC chip carrier package of claim 1, wherein the one or more dielectric wiring layers further comprising a power/ground plane and a second wiring feature upon the IC chip carrier upper surface that is electrically connected to the power/ground plane.

3. The IC chip carrier package of claim 2, wherein the capacitor further comprises a second terminal connected to the second wiring feature.

4. The IC chip carrier package of claim 2, wherein the DMP comprises a non-zero electric potential and the power/ground plane comprises a zero electric potential.

5. The IC chip carrier package of claim 1, wherein the DMP further comprises one or more clearance holes that each form a void through the DMP.

6. The IC chip carrier package of claim 1, further comprising:
an IC chip electrically connected to a grid of wiring features upon the IC carrier upper surface.

7. The IC chip carrier package of claim 1, wherein the DMP is a Nickel Iron alloy DMP.

8. An electronic device comprising:
a core comprising one or more core layers;
a first dielectric wiring layer directly upon the core;
a metal plane dielectric layer directly upon the first dielectric wiring layer;
a dedicated metal plane (DMP) directly upon the metal plane dielectric layer, the DMP comprising a first side surface that is coplanar with a first side surface of the IC chip carrier, a second side surface that is coplanar with a second side surface of the IC chip carrier, a front surface that is coplanar with a front surface of the IC chip carrier, and a rear surface that is coplanar with a rear surface of the IC chip carrier;
one or more dielectric wiring layers directly upon the DMP, the one or more dielectric wiring layers comprising a first wiring feature upon the IC chip carrier upper surface that is electrically connected to the DMP; and
a capacitor connected to the IC chip carrier upper surface, the capacitor comprising a first terminal connected to the first wiring feature.

9. The electronic device of claim 8, wherein the one or more dielectric wiring layers further comprising a power/ground plane and a second wiring feature upon the IC chip carrier upper surface that is electrically connected to the power/ground plane.

10. The electronic device of claim 8, wherein the capacitor further comprises a second terminal connected to the second wiring feature.

11. The electronic device of claim 9, wherein the DMP comprises a non-zero electric potential and the power/ground plane comprises a zero electric potential.

12. The electronic device of claim 8, wherein the DMP further comprises one or more clearance holes that each form a void through the DMP.

13. The electronic device of claim 8, further comprising:
an IC chip electrically connected to a first grid of wiring features upon the IC carrier upper surface; and
a mother board electrically connected to second grid of wiring features upon the IC carrier bottom surface.

14. The electronic device of claim 8, wherein the DMP is a Nickel Iron alloy DMP.

15. An integrated circuit (IC) chip carrier comprising:
a core comprising one or more core layers;
a first dielectric wiring layer directly upon the core;
a metal plane dielectric layer directly upon the first dielectric wiring layer;
a dedicated metal plane (DMP) directly upon the metal plane dielectric layer, the DMP comprising a first side surface that is coplanar with a first side surface of the IC chip carrier, a second side surface that is coplanar with a second side surface of the IC chip carrier, a front surface that is coplanar with a front surface of the IC chip carrier, and a rear surface that is coplanar with a rear surface of the IC chip carrier;
one or more dielectric wiring layers directly upon the DMP, the one or more dielectric wiring layers comprising a first wiring feature upon the IC chip carrier upper surface that is electrically connected to the DMP; and
a capacitor connected to the IC chip carrier upper surface, the capacitor comprising a first terminal connected to the first wiring feature.

16. The IC chip carrier of claim 15, wherein the one or more dielectric wiring layers further comprising a power/ground plane and a second wiring feature upon the IC chip carrier upper surface that is electrically connected to the power/ground plane.

17. The IC chip carrier of claim 16, wherein the capacitor further comprises a second terminal connected to the second wiring feature.

18. The IC chip carrier of claim 17, wherein the DMP comprises a non-zero electric potential and the power/ground plane comprises a zero electric potential.

19. The IC chip carrier of claim 15, wherein the DMP further comprises one or more clearance holes that each form a void through the DMP.

20. The IC chip carrier of claim 15, wherein the DMP is a Nickel Iron alloy DMP.
